(19) United States
(12) Patent Application Publication
(10) Pub. No.: US 2025/0343423 A1
(43) Pub. Date: Nov. 6, 2025

(54) APPARATUS AND METHOD FOR BATTERY CELL BALANCING

(71) Applicant: SK On Co., Ltd., Seoul (KR)

(72) Inventors: Yong Sug CHOI, Daejeon (KR); Jeong Min SEO, Daejeon (KR); Bo Youn YOO, Daejeon (KR)

(21) Appl. No.: 19/195,124

(22) Filed: Apr. 30, 2025

(30) Foreign Application Priority Data
May 3, 2024 (KR) 10-2024-0059447

(51) Int. Cl. H02J 7/00

(52) U.S. Cl. CPC H02J 7/0019; H02J 7/00712

(57) ABSTRACT

Proposed are an apparatus and a method for battery cell balancing. The apparatus includes passive balancing resistors respectively connected in parallel to battery cells, passive balancing switches respectively connected in series to the passive balancing resistors and connecting or disconnecting the passive balancing resistors in parallel to or from the battery cells, a charging element converting power and supplying a result of conversion to the battery cells, switching elements respectively connected to the battery cells and connecting or disconnecting the battery cells to or from the charging element, and a battery management system sensing states of charge of the battery cells and controlling the passive balancing switches or the switching elements such that active balancing is performed on one battery cell with the lowest state of charge and passive balancing is performed on one or more battery cells with the states of charge higher than a reference value.

### CROSS REFERENCE TO RELATED APPLICATION

The present application claims priority to Korean Patent Application No. 10-2024-0059447, filed May 3, 2024, the entire contents of which is incorporated herein for all purposes by this reference.

### TECHNICAL FIELD

The present disclosure relates to an apparatus and a method for battery cell balancing.

### BACKGROUND

A battery pack used as the power source of an electric vehicle or a battery rack of an energy storage system (ESS) includes a plurality of battery cells. The plurality of battery cells will experience differences in degradation due to differences in manufacturing processes or differences in usage history. There are differences in the degree of degradation of the plurality of battery cells, which may cause differences in the state of charge (SOC) of the battery cells even if the battery cells are charged for the same amount of time. Battery cell balancing technology can equalize the state of charge between the battery cells. Battery cell balancing technology may include passive balancing, which discharges a battery cell with a high state of charge, and active balancing, which charges a battery cell with a low state of charge. Battery cell balancing technology may be applied to both electric vehicles and energy storage systems.

The foregoing is intended merely to aid in the understanding of the background of the present disclosure, and is not intended to mean that the present disclosure falls within the purview of the related art that is already known to those skilled in the art.

### SUMMARY

According to an aspect of the present disclosure, there are provided an apparatus and a method for battery cell balancing, the apparatus and the method performing active balancing performed on only one battery cell with the lowest state of charge among a plurality of battery cells, and performing passive balancing on the remaining battery cells.

According to an aspect of the present disclosure, there are provided an apparatus and a method for battery cell balancing, the apparatus and the method being capable of diagnosing the states of battery cells while performing balancing operation.

An apparatus and a method for battery cell balancing according to an aspect of the present disclosure are widely applicable to electric vehicles, battery charging stations, and other green technology fields, such as solar power generation and wind power generation using batteries.

An apparatus and a method for battery cell balancing according to an aspect of the present disclosure are usable in eco-friendly electric vehicles and hybrid vehicles for preventing climate change by curbing air pollution and emission of greenhouse gases.

According to an aspect of the present disclosure, there is provided an apparatus for battery cell balancing, the apparatus including: a plurality of passive balancing resistors respectively connected in parallel to a plurality of battery cells; a plurality of passive balancing switches respectively connected in series to the plurality of passive balancing resistors, and configured to connect or disconnect the plurality of passive balancing resistors in parallel to or from the plurality of battery cells; a charging element configured to convert power received from a power source for active balancing and supply a result of conversion to the plurality of battery cells; a plurality of switching elements respectively connected to the plurality of battery cells, and configured to connect or disconnect the plurality of battery cells to or from the charging element; and a battery management system configured to sense a state of charge of each of the plurality of battery cells, and control the plurality of passive balancing switches or the plurality of switching elements such that active balancing is performed on one battery cell with the lowest state of charge among the plurality of battery cells and passive balancing is performed on one or more battery cells with the states of charge higher than a reference value among the plurality of battery cells.

According to an embodiment, each of the plurality of switching elements may include: a first contact point connected to a first output terminal of the charging element from which power for active balancing is output; a second contact point connected to one end of the battery cell; a third contact connected to a second output terminal of the charging element from which power for active balancing is output; and a fourth contact connected to the other end of the battery cell, wherein each of the plurality of switching elements may be configured to connect the first contact point to the second contact point and connect the third contact to the fourth contact when a control signalis input from the battery management system.

According to an embodiment, the charging element may include: a power input terminal configured to receive power from the power source; a ground terminal connected to the ground; a first output terminal from which power for active balancing is output; a second output terminal from which power for active balancing is output; and a power conversion circuit configured to convert power received from the power input terminal and the ground terminal and output a result of conversion to the first output terminal and the second output terminal, and including a first circuit connecting the power input terminal and the ground terminal and a second circuit connecting the first output terminal and the second output terminal, the first and the second circuit being electrically insulated.

According to an embodiment, the power source may be the one or more battery cells with the states of charge higher than the reference value among the plurality of battery cells, a power converter configured to convert commercial power and provide power for active balancing to the charging element, or a balancing battery existing independently of the plurality of battery cells and configured to output power for active balancing.

According to an embodiment, the battery management system may be configured to count, for each of the plurality of battery cells, the number of times that active balancing or passive balancing is performed, and determine that the battery cell is in an abnormal state when an absolute value of a difference between the number of times that active balancing is performed and the number of times that passive balancing is performed is greater than a reference number of times.

According to an embodiment, the battery management system may be configured to compare a current corresponding to a voltage of each of the plurality of battery cells to a determined range in a reference graph while active balancing or passive balancing is performed, and determine that, when the current corresponding to the voltage of the battery cell is out of the determined range in the reference graph, the battery cell is in an abnormal state.

According to an embodiment, the battery management system may include: a module management system configured to manage a battery module including the plurality of battery cells; a rack management system configured to manage a battery rack including a plurality of the battery modules; and an energy management system configured to manage an energy storage system including a plurality of the battery racks.

According to an embodiment, the module management system may be configured to output a control signal for performing active balancing and passive balancing of the plurality of battery cells, the rack management system may be configured to control the module management system such that active balancing and passive balancing of the plurality of battery cells are performed, count, for each of the plurality of battery cells, the number of times that active balancing is performed and the number of times that passive balancing is performed, and determine that the battery cell is in an abnormal state when an absolute value of a difference between the number of times that active balancing is performed and the number of times that passive balancing is performed is greater than a reference value, and compare a voltage and a current of each of the plurality of battery cells to a determined range in a reference graph, and determine that, when the voltage and the current of the battery cell is out of the determined range in the reference graph, the battery cell is in the abnormal state, and the energy management system may be configured to control the module management system and the rack management system, and forward active balancing results, passive balancing results, and results of diagnosing the plurality of battery cells to a high-level system.

According to an aspect of the present disclosure, there is provided a method for battery cell balancing, the method including: sensing, by a battery management system, states of charge of a plurality of battery cells; determining, by the battery management system, whether each of the plurality of battery cells satisfies an active balancing condition; controlling, by the battery management system, a switching element connected to the battery cell satisfying the active balancing condition and performing active balancing in which a charging element outputting power is connected to the battery cell satisfying the active balancing condition; determining, by the battery management system, whether each of the plurality of battery cells satisfies a passive balancing condition; and controlling, by the battery management system, a plurality of passive balancing switches respectively connected to one or more battery cells satisfying the passive balancing condition among the plurality of battery cells and performing passive balancing in which the one or more battery cells satisfying the passive balancing condition are connected to passive balancing resistors connected to the one or more battery cells.

According to an embodiment, the method for battery cell balancing may further include determining whether the states of charge of all of the plurality of battery cells are in a determined range, wherein balancing may be terminated when the states of charge of the plurality of battery cells are in the determined range, or feedback may be provided to start balancing again from the beginning when any battery cell with the state of charge out of the determined range exists among the plurality of battery cells.

According to an embodiment, the active balancing condition may mean among the plurality of battery cells, a difference between a voltage of the battery cell with the lowest state of charge and a voltage of the battery cell with the next lowest state of charge is greater than a reference value, and the passive balancing condition may mean among the remaining battery cells other than the battery cell satisfying the active balancing condition, a deviation of a voltage of the battery cell is greater than a reference deviation.

According to an embodiment, the switching element may include: a first contact point connected to a first output terminal of the charging element from which power for active balancing is output; a second contact point connected to one end of the battery cell; a third contact connected to a second output terminal of the charging element from which power for active balancing is output; and a fourth contact connected to the other end of the battery cell, and in the performing of active balancing, when the battery management system inputs a control signal to the switching element, the first contact point is connected to the second contact point and the third contact is connected to the fourth contact and the battery cell with the lowest state of charge is charged with power output by the charging element.

According to an embodiment, the method for battery cell balancing may further include: after the performing of active balancing, a first counting step of increasing the number of times that active balancing is performed on the battery cell subjected to active balancing; after the performing of passive balancing, a second counting step of increasing the number of times that passive balancing is performed on the battery cell subjected to passive balancing; determining whether an absolute value of a difference between the number of times that active balancing is performed and the number of times that passive balancing is performed is greater than a reference number of times; determining that the battery cell is in an abnormal state when the absolute value of the difference between the number of times that active balancing is performed and the number of times that passive balancing is performed is greater than the reference number of times; and determining that the battery cell is in a normal state the absolute value of the difference between the number of times that active balancing is performed and the number of times that passive balancing is performed is equal to or less than the reference number of times.

According to an embodiment, the method for battery cell balancing may further include: measuring voltages and currents of the plurality of battery cells while active balancing is performed; measuring voltages and currents of the plurality of battery cells while passive balancing is performed; determining whether the current corresponding to the voltage of each of the plurality of battery cells is out of a determined range in a reference graph while active balancing or passive balancing is performed; determining that, when the current corresponding to the voltage of the battery cell is out of the determined range in the reference graph, the battery cell is in an abnormal state; and determining that, when the current corresponding to the voltage of the battery cell is in the determined range in the reference graph, the battery cell is in a normal state.

According to an embodiment, the battery management system may include a module management system configured to manage a battery module including the plurality of battery cells; a rack management system configured to manage a battery rack including a plurality of the battery modules; and an energy management system configured to manage an energy storage system including a plurality of the battery racks, and the determining of whether the active balancing condition is satisfied and the determining of whether the passive balancing condition is satisfied may be performed by the rack management system, and the performing of active balancing and the performing of passive balancing may be performed by the module management system.

The features and advantages of the present disclosure will be more clearly understood from the following detailed description based on the accompanying drawings.

The terms and words used in the present specification and claims should not be interpreted as being limited to typical meanings and dictionary definitions, but should be interpreted as having meanings and concepts relevant to the technical scope of the present disclosure based on the rule according to which an inventor can appropriately define the concept of the term to describe most appropriately the best method he or she knows for carrying out the present disclosure.

According to an embodiment of the present disclosure, one battery cell with a low state of charge is charged and the remaining battery cells with a high state of charge are discharged, thereby rapidly performing balancing and minimizing wasted energy.

According to an embodiment of the present disclosure, the states of the battery cells can be diagnosed while balancing operation is performed, thereby monitoring the states of the battery cells regularly.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a diagram illustrating an apparatus for battery cell balancing according to an embodiment;

FIG. 2 is a diagram illustrating an apparatus for battery cell balancing that receives active balancing power from an external power source, according to an embodiment;

FIG. 3 is a diagram illustrating an apparatus for battery cell balancing that receives active balancing power from battery cells, according to an embodiment;

FIG. 4 is a diagram illustrating each step of a method for battery cell balancing according to an embodiment;

FIG. 5 is a diagram illustrating a diagnosis step based on the number of times that balancing is performed, according to an embodiment;

FIG. 6 is a diagram illustrating a diagnosis step based on currents corresponding to voltages, according to an embodiment;

FIG. 7 is a diagram illustrating a reference graph used for diagnosis during active balancing, according to an embodiment; and

FIG. 8 is a diagram illustrating a reference graph used for diagnosis during passive balancing, according to an embodiment.

### DETAILED DESCRIPTION

Hereinafter, the present disclosure will be described in detail (with reference to the accompanying drawings). However, this is merely illustrative and the present disclosure is not limited to the specific embodiments described by way of example.

Hereinafter, an embodiment of the present disclosure will be described in detail with reference to the accompanying drawings.

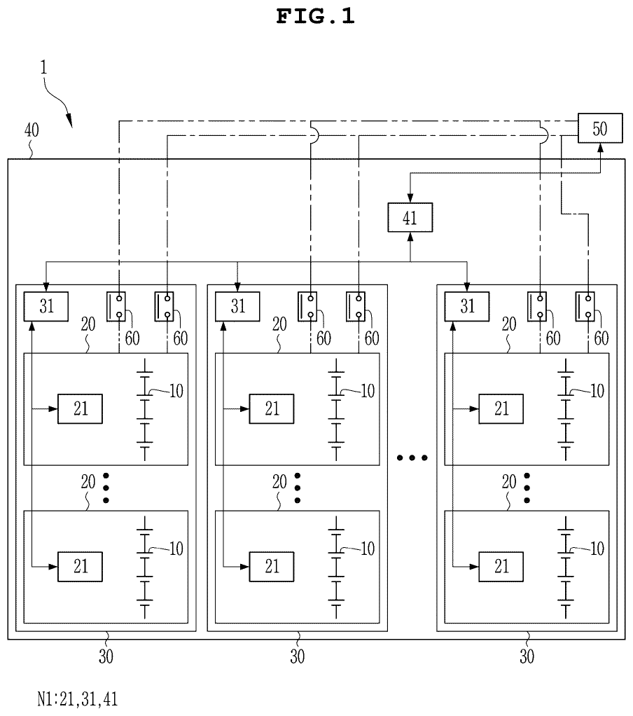

FIG. 1 is a diagram illustrating an apparatus 1 for battery cell balancing according to an embodiment.

In FIG. 1, the connections through which module management systems 21, rack management systems 31, an energy management system 41, and a battery control panel 50 transmit and receive commands or data are denoted by solid line arrows. In FIG. 1, the connections through which between battery modules 20, battery racks 30, and the battery control panel 50 transmit and receive power are denoted by dashed single-dotted lines and dashed double-dotted lines.

The apparatus 1 for battery cell balancing according to an embodiment may be applied to an energy storage system (ESS) 40 or a battery pack of an electric vehicle. Herein, a description will be given based the apparatus 1 for battery cell balancing applied to the energy storage system 40.

The energy storage system 40 may include a plurality of battery racks 30. Each battery rack 30 may include a plurality of battery modules 20. Each battery module 20 may include a plurality of battery cells 10. The battery cells 10 may include various types of cells, such as quadrangular, cylindrical, and pouch-shaped battery cells. The battery cells 10 are secondary batteries that can be charged and discharged. Power relays 60 may connect the battery control panel 50 and the battery racks 30. The power relays 60 may be controlled to be open in the event of a short circuit, fire, overcharging, or a variety of other incidents. The rack management systems 31 may control turning on or off the power relays 60.

The apparatus 1 for battery cell balancing according to an embodiment may control switches included in the circuit such that a battery management system (N1) senses the states of charge of the battery cells 10 and performs active balancing on one battery cell 10 with the lowest state of charge and performs passive balancing on one or more battery cells 10 with a high state of charge. The battery cell 10 with a high state of charge has a high voltage, and the battery cell 10 with a low state of charge has a low voltage. Thus, a high or low state of charge may also be said to mean that the voltage of the battery cell 10 is high or low.

The battery management system (BMS) (N1) may include: the module management systems 21 for managing the plurality of battery modules 20 each including the plurality of battery cells 10; the rack management systems 31 for managing the plurality of battery racks 30 each including the plurality of battery modules 20; and the energy management system 41 for managing the energy storage system 40 including the plurality of battery racks 30. All the module management systems 21, the rack management systems 31, and the energy management system 41 are the battery management system (N1). The battery management system (N1) may include one or more semiconductor chips and memories. While transmitting and receiving commands and data, the module management systems 21 and the rack management systems 31 may perform a method for battery cell balancing according to an embodiment.

The module management systems 21 may output control signals for operating the switches for charging, discharging, or balancing of the battery cells 10. The module management systems 21 may output control signals for performing active balancing and passive balancing of the battery cells 10.

The rack management systems 31 may determine whether to perform charging, discharging, or balancing of the battery cells 10, and may output control signals to the module management systems 21. The rack management systems 31 may control the module management systems 21 such that active balancing and passive balancing of the battery cells 10 are performed. The rack management system 31 may diagnose the states of battery cells 10. The rack management system 31 may count the number of times that active balancing is performed and the number of times that passive balancing is performed, for each of the plurality of battery cells 10. For a particular battery cell 10, when an absolute value of a difference between the number of times that active balancing is performed and the number of times that passive balancing is performed is greater than a reference value, the rack management system 31 may determine that the battery cell 10 is in an abnormal state. The rack management system 31 may compare the voltage and the current of each of the plurality of battery cells 10 to a range determined in a reference graph. For a particular battery cell 10, when the voltage and the current are out of the range determined in the reference graph, the rack management system 31 may determine that the battery cell 10 is in an abnormal state.

The energy management system 41 may forward, to a high-level system, the states of charge, the states of discharge, and balancing results of the plurality of battery racks 30, and results of diagnosing the battery cells 10. The energy management system 41 may control the module management systems 21 and the rack management systems 31, and may forward active balancing, passive balancing, and abnormal state diagnosis results to the high-level system.

The energy storage system 40 may include the battery control panel (BCP) 50 that controls power charged or discharged in the plurality of battery racks 30. The battery control panel 50 is the high-level system of the energy management system 41, and may display, to a manager, the states of charge, the states of discharge, and the balancing states of the energy storage system 40, and the results of diagnosing the battery cell 10. The battery control panel 50 may be connected to an external load or commercial power grid to input or output the power stored in the energy storage system 40.

When a method for battery cell balancing according to an embodiment is applied to an electric vehicle, the functions performed by the rack management systems 31 may be performed by a pack management system that manages a battery pack of the electric vehicle.

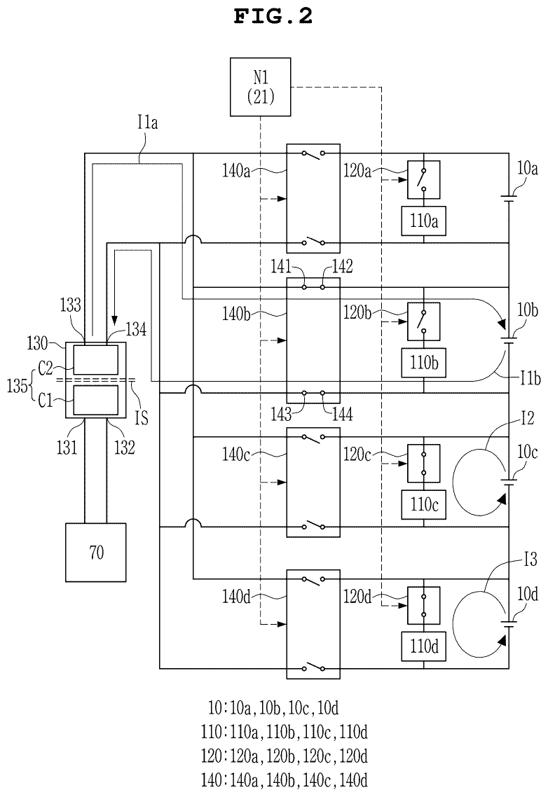

FIG. 2 is a diagram illustrating an apparatus 1 for battery cell balancing that receives active balancing power from an external power source, according to an embodiment.

In FIG. 2, the lines through which control signals are output from the battery management system (N1) to switching elements 140 or passive balancing switches 120 are denoted by dotted lines.

The apparatus 1 for battery cell balancing according to an embodiment may include: a plurality of passive balancing resistors 110 respectively connected in parallel to a plurality of battery cells 10; a plurality of passive balancing switches 120 respectively connected in series to the plurality of passive balancing resistors 110, and configured to connect or disconnect the plurality of passive balancing resistors 110 in parallel to or from the plurality of battery cells 10; a charging element 130 configured to convert power received from a power source for active balancing and supply a result of conversion to the plurality of battery cells 10; a plurality of switching elements 140 respectively connected to the plurality of battery cells 10, and configured to connect or disconnect the plurality of battery cells 10 to or from the charging element 130; and a battery management system (N1) configured to sense a state of charge of each of the plurality of battery cells 10, and control the plurality of passive balancing switches 120 or the plurality of switching elements 140 such that active balancing is performed on one battery cell 10 with the lowest state of charge among the plurality of battery cells 10 and passive balancing is performed on one or more battery cells 10 with the states of charge higher than a reference value among the plurality of battery cells 10.

The passive balancing resistor 110 and the passive balancing switch 120 may be connected to each other in series, and may be connected in parallel to the battery cell 10. The passive balancing resistors 110 and the passive balancing switches 120 may be connected to the respective battery cells 10. When the passive balancing switch 120 is turned on, the passive balancing resistor 110 is connected to the battery cell 10 and the power of the battery cell 10 is consumed by the passive balancing resistor 110 and passive balancing may be performed. When the passive balancing switch 120 is turned off, the passive balancing resistor 110 is disconnected from the battery cell 10 and passive balancing may be stopped. The passive balancing switch 120 may be turned on or off by a control signal provided by the battery management system (N1). Specifically, the module management system 21 may output the control signal for turning on or off the passive balancing switch 120.

The charging element 130 may convert the power received from the power source for active balancing into a voltage and a current for charging the battery cell 10 and may output the same. The charging element 130 may be a power semiconductor chip. The charging element 130 may include: a power input terminal 131 for receiving power from the power source; a ground terminal 132 connected to the ground; a first output terminal 133 from which power for active balancing is output; a second output terminal 134 from which power for active balancing is output; and a power conversion circuit 135 for converting power received from the power input terminal 131 and the ground terminal 132 and outputting a result of conversion to the first output terminal 133 and the second output terminal 134, and including a first circuit (C1) connecting the power input terminal 131 and the ground terminal 132 and a second circuit (C2) connecting the first output terminal 133 and the second output terminal 134, the first circuit (C1) and the second circuit (C2) being electrically insulated. The power input terminal 131, the ground terminal 132, the first output terminal 133, and the second output terminal 134 are input and output terminals of the charging element 130.

The power source may be one selected from the group of a power converter 70 converting commercial power and providing power for active balancing to the charging element 130, and a balancing battery existing independently of the plurality of battery cells 10 and outputting power for active balancing. This power source may be referred to as an external power source. This means that the external power source is not the battery cells 10 belonging to the energy storage system 40. The external power source may include renewable energy sources such as solar cells and a wind power generator.

The charging element 130 may receive power via the power input terminal 131 and the ground terminal 132 connected to the power converter 70, which is the external power source, or a battery cell 10 for balancing. The power converter 70 may supply the power of 24 V or 12V. The battery cell 10 for balancing may include a lead-acid battery for supplying the power of 24 V or 12 V. The charging element 130 may include the power conversion circuit 135 for converting the power received through the power input terminal 131 and the ground terminal 132. The power conversion circuit 135 may be formed in a structure in which the first circuit (C1) connecting the power input terminal 131 and the ground terminal 132 and the second circuit (C2) connecting the first output terminal 133 and the second output terminal 134 are electrically insulated and magnetically connected using electromagnetic coupling. The power conversion circuit 135 may convert the power to a charge voltage (e.g., 4.2 V) of the battery cell 10 and may output the power to the first output terminal 133 and the second output terminal 134. The first output terminal 133 and the second output terminal 134 may be connected to the battery cell 10 through the switching element 140.

The switching element 140 may include: a first contact point 141 connected to the first output terminal 133 of the charging element 130 from which power for active balancing is output; a second contact point 142 connected to one end of the battery cell 10; a third contact 143 connected to the second output terminal 134 of the charging element 130 from which power for active balancing is output; and a fourth contact 144 connected to the other end of the battery cell 10. The switching element 140 may operate, when a control signal is input from the battery management system (N1), to connect the first contact point 141 to the second contact point 142 and connect the third contact 143 to the fourth contact 144. The switching element 140 may output, through the second contact point 142 and the fourth contact 144, the power received through the first contact point 141 and the third contact 143.

The switching elements 140 may be connected to the respective battery cells 10. The switching element 140 may be connected to the charging element 130 to forward power for active balancing. The switching element 140 may be turned on or off by a control signal provided by the battery management system (N1). Specifically, the switching element 140 may be turned on or off by a control signal output by the module management system 21. When the switching element 140 is turned on, the first contact point 141 may be connected to the second contact point 142 and the third contact 143 may be connected to the fourth contact 144. When the switching element 140 is turned off, the first contact point 141 and the second contact point 142 may be disconnected from each other and the third contact 143 and the fourth contact 144 may be disconnected from each other. When the switching element 140 is turned on, the battery cell 10 may be connected to the charging element 130 and active balancing may be performed to charge the battery cell 10.

The battery management system (N1) may sense the state of charge of each of the plurality of battery cells 10. The state of charge (SOC) may indicate the amount of power stored in the battery cell 10. The state of charge may be represented as 100% when the battery cell 10 is fully charged, or may be represented as 0% when the battery cell 10 is fully discharged. Specifically, the module management system 21 may sense the state of charge of each of the plurality of battery cells 10 and may transmit the same to the rack management system 31.

The battery management system (N1) may select the battery cell 10 with the lowest state of charge from the plurality of battery cells 10, and may perform active balancing only on the battery cell 10 with the lowest state of charge. That is, the battery management system (N1) may select the battery cell 10 with the lowest voltage from the plurality of battery cells 10, and may perform active balancing only on the battery cell 10 with the lowest voltage.

Repeated charging and discharging of the plurality of battery cells 10 tends to accelerate the degradation of one battery cell 10 that degrades the fastest among the plurality of battery cells 10. Thus, the phenomenon that any one of the plurality of battery cells 10 has the lowest state of charge may be repeated. The apparatus 1 for battery cell balancing according to an embodiment performs active balancing by charging one battery cell 10 with the lowest state of charge, thereby preventing the phenomenon that degradation of a particular battery cell 10 is accelerated.

The apparatus 1 for battery cell balancing according to an embodiment does not perform active balancing on the plurality of battery cells 10, but performs active balancing on only one battery cell 10 with the lowest state of charge, thus minimizing the time required for active balancing. While active balancing of a plurality of battery cells 10 complicates a switching circuit for selecting each of the battery cells 10, the apparatus 1 for battery cell balancing according to an embodiment performs active balancing on only one battery cell 10 with the lowest state of charge, making the circuit relatively simple.

The battery management system (N1) may perform passive balancing on one or more battery cells 10 with a high state of charge. Performing active balancing is to increase the state of charge of the battery cell 10 with the lowest state of charge. Passive balancing is to decrease the state of charge of the battery cell 10 with a high state of charge. The battery management system (N1) may select the battery cells 10 with states of charge higher than a reference value, and may control the passive balancing switches 120 connected to the battery cells 10 such that the passive balancing switches 120 are turned on. The battery management system (N1) may control the passive balancing switches 120 such that the passive balancing switches 120 are turned off when the states of charge of the battery cells 10 are lower than the determined reference value.

Balancing the plurality of battery cells 10 using only passive balancing is very wasteful of the power stored in the batteries. The apparatus 1 for battery cell balancing according to an embodiment may perform balancing by increasing the state of charge of the battery cell 10 with a low state of charge using active balancing and by discharging the battery cell 10 with a high state of charge using passive balancing. Accordingly, power waste during the balancing process can be minimized.

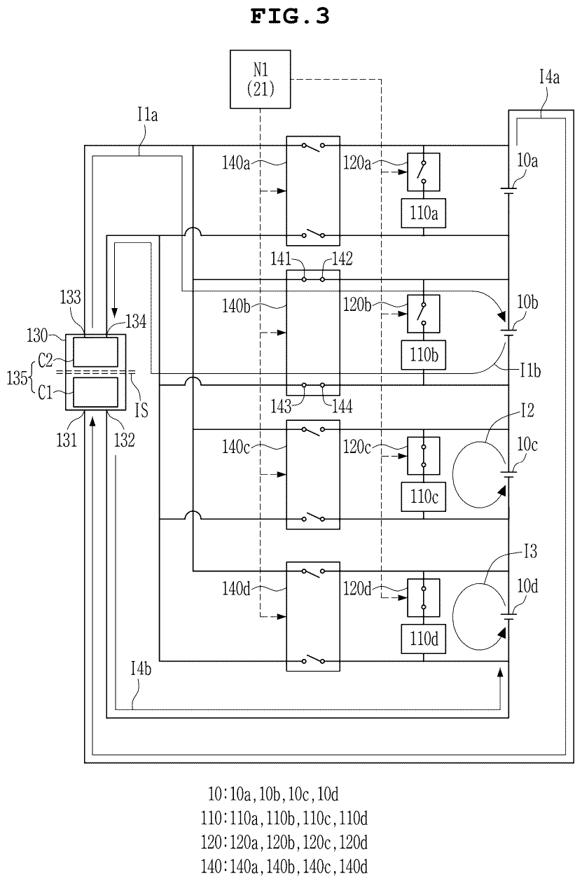

FIG. 3 is a diagram illustrating an apparatus 1 for battery cell balancing that receives active balancing power from battery cells 10, according to an embodiment.

A charging element 130 does not receive power from an external power source, but may receive power from the battery cells 10 included in an energy storage system 40. A power source may include one or more battery cells 10 with a high state of charge among the plurality of battery cells 10. This method uses the power of the battery cells 10 of the energy storage system 40, so the power source may be referred to as an internal power source.

A power input terminal 131 and the ground 132 of the charging element 130 may be connected to the battery cells 10 included in the energy storage system 40. The charging element 130 may be connected to plurality of battery cells 10 connected in series. The output of the plurality of battery cells 10 connected in series may be supplied to the power input terminal 131 and the ground 132 of the charging element 130. The charging element 130 may convert the output of the plurality of battery cells 10 into the voltage for active balancing of one battery cell 10 and may output the voltage. A power conversion circuit 135 of the charging element 130 is electrically insulated internally, so a short circuit does not occur.

FIGS. 2 and 3 will be referenced together.

A description of an embodiment will be given based on a circuit in which a battery module includes a first battery cell 10a to a fourth battery cell 10d, and the plurality of battery cells 10 are respectively connected with a first passive balancing resistor 110a to a fourth passive balancing resistor 110c, a first passive balancing switch 120a to a fourth passive balancing switch 120d, and a first switching element 140a to a fourth switching element 140d. One charging element 130 may exist for each battery module 20. Alternatively, one charging element 130 may exist for each battery rack 30.

As a result of sensing the states of charge of the first to the fourth battery cell 10d, the battery management system (N1) may determine that the battery cell 10 with the lowest state of charge is the second battery cell 10b and the battery cells 10 with the states of charge higher than a reference value or higher than a reference value by a determined deviation or more are the third battery cell 10c and the fourth battery cell 10d. The battery management system (N1) may input a control signal to the second switching element 140b to connect a first contact point 141 and a second contact point 142 of the second switching element 140b and connect a third contact 143 and a fourth contact 144 of the second switching element 140b. When the second switching element 140b is turned on and the charging element 130 is connected to the second battery cell 10b, the power output by the charging element 130 may be input to the second battery cell 10b to charge the second battery cell 10b.

The battery management system (N1) may output control signals to the third passive balancing switch 120c and the fourth passive balancing switch 120d. When the third passive balancing switch 120c is turned on, the third passive balancing resistor 110c is connected to the third battery cell 10c and the third passive balancing resistor 110c may consume the power of the third battery cell 10c. When the fourth passive balancing switch 120d is turned on, the fourth passive balancing resistor 110d is connected to the fourth battery cell 10d and the fourth passive balancing resistor 110d may consume the power of the fourth battery cell 10d.

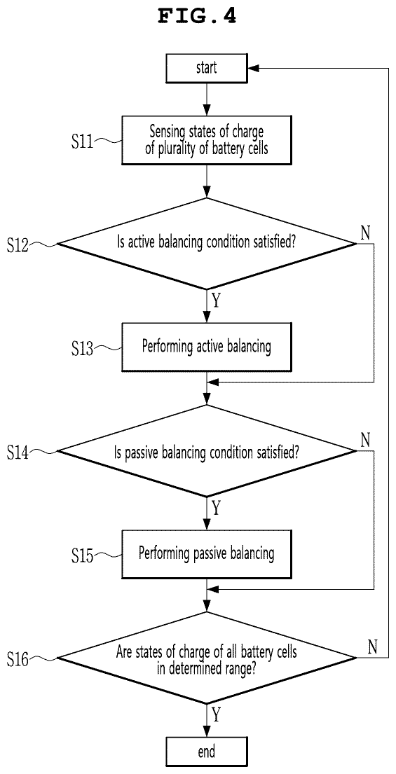

FIG. 4 is a diagram illustrating each step of a method for battery cell balancing according to an embodiment.

The method for battery cell balancing according to an embodiment may include: sensing, by a battery management system (N1), states of charge of a plurality of battery cells 10 in step S11; determining, by the battery management system (N1), whether each of the plurality of battery cells satisfies an active balancing condition in step S12; controlling, by the battery management system (N1), a switching element 140 connected to the battery cell 10 satisfying the active balancing condition and performing active balancing in which a charging element 130 outputting power is connected to the battery cell 10 satisfying the active balancing condition in step S13; determining, by the battery management system (N1), whether each of the plurality of battery cells 10 satisfies a passive balancing condition in step S14; controlling, by the battery management system (N1), a plurality of passive balancing switches 120 respectively connected to one or more battery cells 10 satisfying the passive balancing condition and performing passive balancing in which the one or more battery cells 10 satisfying the passive balancing condition are connected to passive balancing resistors 110 connected to the one or more battery cells 10 in step S15.

As described above with reference to FIG. 1, the battery management system (N1) may include the module management systems 21, the rack management systems 31, and the energy management system 41. The determining of whether the active balancing condition is satisfied in step S12 and the determining of whether the passive balancing condition is satisfied in step S14 may be performed by the rack management systems 31. The performing of active balancing in step S13 and the performing of passive balancing in step S15 may be performed by the module management systems 21.

The method for battery cell balancing may be performed at determined intervals. The sensing of the states of charge of the battery cells 10 by the battery management system (N1) in step S11 may be performed at determined intervals. The sensing of the states of charge of the battery cells 10 in step S11 may be performed by the module management systems 21. After sensing the states of charge of the battery cells 10, the battery management system (N1) may perform the determining of whether the active balancing condition is satisfied in step S12.

The determining of whether the active balancing condition is satisfied in step S12 may be performed by the rack management systems 31. The active balancing condition may include a condition in which among the plurality of battery cells 10, a difference between the voltage of the battery cell 10 with the lowest state of charge and the voltage of the battery cell 10 with the next lowest state of charge is greater than a reference value. The battery cell 10 satisfying the active balancing condition may be the battery cell 10 with the lowest state of charge among the plurality of battery cells 10, and may be the battery cell 10 of which the voltage is different from the voltage of the battery cell 10 with the next lowest state of charge by more than the reference value. For example, if the state of charge of the second battery cell 10b is the lowest and the state of charge of the first battery cell 10a is the next lowest, when the difference between the voltage of the second battery cell 10b and the voltage of the first battery cell 10a is greater than the reference voltage, it may be determined that the second battery cell 10b satisfies the active balancing condition. The reference voltage may be determined in a range of a few mV to several tens of mV.

When the battery cell 10 satisfying the active balancing condition exists (Y), the battery management system (N1) may perform active balancing. When there is no battery cell 10 satisfying the active balancing condition (N), the battery management system (N1) may perform the determining of whether the passive balancing condition is satisfied in step S14.

In the performing of active balancing in step S13, the battery management system (N1) inputs a control signal to the switching element 140 to connect the charging element 130 and the battery cell 10. In the performing of active balancing in step S13, when the battery management system (N1) inputs a control signal to the switching element 140, a first contact point 141 is connected to a second contact point 142 and a third contact 143 is connected to a fourth contact 144 and the battery cell 10 with the lowest state of charge is thus charge with the power output by the charging element 130. In the performing of active balancing in step S13, the rack management system 31 may control the module management system 21 such that the module management system 21 outputs the control signal for turning on the switching element 140. In the performing of active balancing in step S13, the switching element 140 may be turned on by the control signal and may connect the charging element 130 to the battery cell 10. In the performing of active balancing in step S13, when the voltage deviation of the battery cell 10 is less than the reference value, active balancing may be stopped.

After active balancing is performed, the determining of whether the passive balancing condition is satisfied in step S14 may be performed.

The determining of whether the passive balancing condition is satisfied in step S14 may be performed by the rack management systems 31. The passive balancing condition may include a condition in which among the remaining battery cells 10 other than the battery cell 10 satisfying the active balancing condition, the deviation of the voltage of the battery cell 10 is greater than a reference deviation. For example, it may be determined that among the remaining battery cells 10 (the first battery cell 10a, the third battery cell 10c, and the fourth battery cell 10d) except the second battery cell 10b subjected to active balancing, all the battery cells 10 of which the deviations of the voltages are greater than the reference deviation satisfy the condition. The reference deviation may be determined in a range of a few mV to several tens of mV. The voltage deviation of the battery cell 10 may be calculated by obtaining the average of the voltages of the plurality of battery cells 10 and obtaining the difference between the average and the voltage of the particular battery cell 10.

When the battery cell 10 satisfying the passive balancing condition exists (Y), the battery management system (N1) may perform passive balancing. When there is no battery cell 10 passive balancing condition (N), the battery management system (N1) may perform determining whether to terminate balancing.

In the performing of passive balancing in step S15, the battery management system (N1) inputs a control signal to the passive balancing switch 120 to connect the passive balancing resistor 110 and the battery cell 10. In the performing of passive balancing in step S15, the rack management system 31 may control the module management system 21 such that the module management system 21 outputs the control signal for turning on the passive balancing switch 120. In the performing of passive balancing in step S15, the passive balancing switch 120 may be turned on by the control signal to connect the passive balancing resistor 110 and the battery cell 10. In the performing of passive balancing in step S15, when the voltage deviation of the battery cell 10 is less than the reference value, passive balancing may be stopped.

The method for battery cell balancing according to an embodiment may further include determining whether the states of charge of all of the battery cells 10 are in a determined range in step S16. When the states of charge of the plurality of battery cells 10 are in the determined range, balancing may be terminated. When any battery cell 10 with the state of charge out of the determined range exists, feedback may be provided to start balancing again from the beginning. The determined range may mean that the voltage deviation of the battery cell 10 is less than the reference value. The reference value may be stored in the battery management system (N1).

The determining of whether the states of charge of all of the battery cells 10 are in the determined range in step S16 may be performed after active balancing or passive balancing is performed. When the states of charge of all of the battery cells 10 are in the determined range (Y), balancing may be terminated. When any battery cell 10 with the state of charge out of the determined range exists (N), balancing may start again from the beginning.

The apparatus 1 and method for battery cell balancing according to an embodiment may diagnose the states of the battery cells 10 while performing balancing.

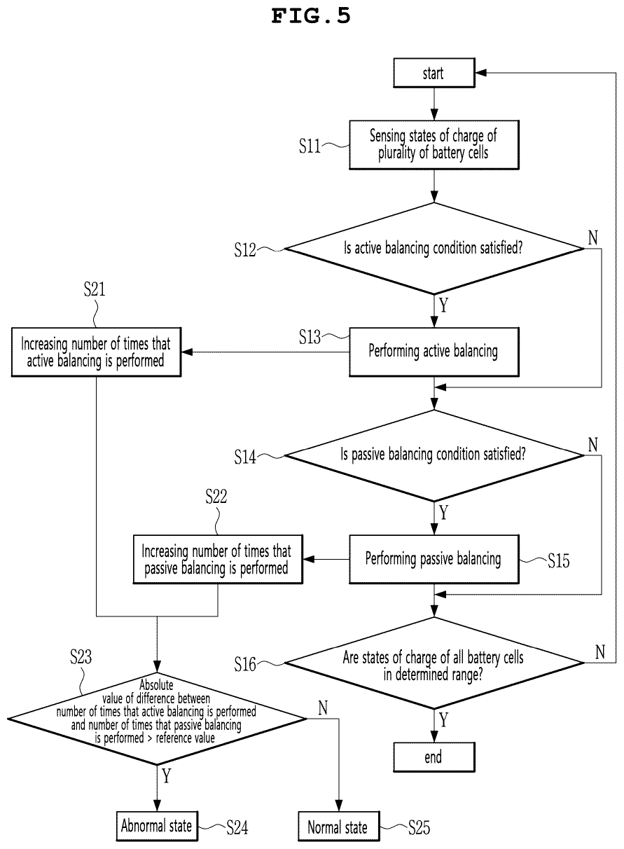

FIG. 5 is a diagram illustrating a diagnosis step based on the number of times that balancing is performed, according to an embodiment.

The battery management system (N1) may count the number of times that active balancing or passive balancing is performed, for each of the plurality of battery cells 10, and may determine that the battery cell 10 is in an abnormal state when an absolute value of a difference between the number of times that active balancing is performed and the number of times that passive balancing is performed is greater than a reference number of times. Repeatedly performing active balancing or passive balancing on a particular cell means that the battery cell 10 is in an abnormal state. For example, a battery cell 10 selected to be subjected to active balancing means that the battery cell 10 has a lower state of charge than other battery cells 10 when charged or discharged for the same amount of time. Therefore, it may be determined that a battery cell 10 frequently subjected to active balancing is abnormal. In addition, the absolute value of the difference between the number of times that passive balancing is performed and the number of times that active balancing is performed is used as a determination target to select the battery cell 10 subjected to passive balancing very few times, or the battery cell 10 subjected to active balancing very many times.

The method for battery cell balancing may include: a first counting step S21 of increasing the number of times that active balancing is performed on the battery cell 10 subjected to active balancing after the performing of active balancing in step S13; a second counting step S22 of increasing the number of times that passive balancing is performed on the battery cell 10 subjected to passive balancing after the performing of passive balancing in step S15; determining whether an absolute value of a difference between the number of times that active balancing is performed and the number of times that passive balancing is performed is greater than a reference number of times in step S23; determining that the battery cell 10 is in an abnormal state when the absolute value of the difference between the number of times that active balancing is performed and the number of times that passive balancing is performed is greater than the reference number of times in step S24; and determining that the battery cell 10 is in a normal state when the absolute value of the difference between the number of times that active balancing is performed and the number of times that passive balancing is performed is equal to or less than the reference number of times in step S25.

The first counting step S21 may be performed after active balancing is performed. The first counting step S21 is to increase by one the number of times that active balancing is performed on the battery cell 10 subjected to active balancing. When active balancing is repeatedly performed on a particular battery cell 10, the number of times that active balancing is performed on the battery cell 10 may continue to increase.

The second counting step S22 may be performed after passive balancing is performed. The second counting step S22 is to increase by one the number of times that passive balancing is performed on the battery cell 10 subjected to passive balancing. When passive balancing is repeatedly performed on a particular battery cell 10, the number of times that passive balancing is performed on the battery cell 10 may increase continuously.

The first counting step S21 and the second counting step S22 may be performed by the rack management systems 31.

The determining of whether the absolute value of the difference between the number of times that active balancing is performed and the number of times that passive balancing is performed is greater than the reference number of times in step S23 may be performed after the first counting step S21 and the second counting step S22 are performed. Specifically, the difference is calculated by subtracting the number of times that passive balancing is performed from the number of times that active balancing is performed, and the absolute value of the difference may be compared to the reference number of times.

When the absolute value of the difference between the number of times that active balancing is performed and the number of times that passive balancing is performed is greater than the reference number of times (Y), it may be determined that the battery cell 10 is in the abnormal state. When the number of times that active balancing is performed is significantly greater than the number of times that passive balancing is performed, the battery cell 10 may be classified as in an abnormal state because the battery cell 10 is a cell of which the state of charge decreases rapidly due to severe degradation even if charged or discharged for the same amount of time.

The battery cell on which the number of times that passive balancing is performed is greater than the number of times that active balancing is performed may be an abnormal battery cell. A very high number of times that passive balancing is performed may mean that the battery cell is poorly discharged or has a rapidly increasing voltage when charged, and the battery cell may be classified as in the abnormal state, compared to general battery cells.

When the absolute value of the difference between the number of times that active balancing is performed and the number of times that passive balancing is performed is equal to or less than the reference number of times (N), it may be determined that the battery cell 10 is in the normal state. This is because the battery cell 10 in the normal state is unlikely to be subjected to active balancing and its state of charge may remain relatively high.

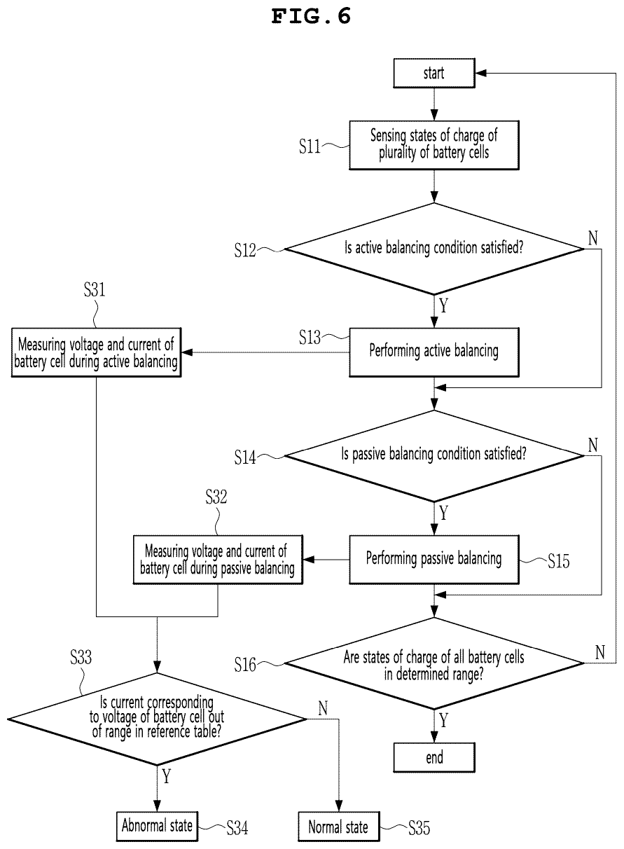

FIG. 6 is a diagram illustrating a diagnosis step based on currents corresponding to voltages, according to an embodiment.

While active balancing or passive balancing is performed, the battery management system (N1) may compare the current corresponding to the voltage of each of the plurality of battery cells to a determined range in a reference graph, and may determine that, when the current corresponding to the voltage of the battery cell 10 is out of the determined range in the reference graph, the battery cell 10 is in an abnormal state.

In the charging or discharging process, a constant current value corresponding to a particular voltage of the battery cell 10 in the normal state may be measured. In the charging or discharging process, a rapidly decreasing or increasing current value corresponding to a particular voltage of the battery cell 10 in the abnormal state may be measured. Since the voltage and current values measured during charging through active balancing and discharging through passive balancing are used and compared to the reference graph to diagnose the battery cell 10, there is no need for tests for separate diagnosis.

A method for battery cell balancing according to an embodiment may include: measuring a voltage and a current of the battery cell 10 while active balancing is performed in step S31; measuring a voltage and a current of the battery cell 10 while passive balancing is performed in step S32; determining whether a current corresponding to a voltage of each of the plurality of battery cells 10 is out of a determined range in a reference graph while active balancing or passive balancing is performed in step S33; determining that the battery cell 10 is in an abnormal state when the current corresponding to the voltage of the battery cell 10 is out of the determined range in the reference graph in step S34; and determining that the battery cell 10 is in a normal state when the current corresponding to the voltage of the battery cell 10 is in the determined range in the reference graph in step S35.

The measuring of the voltage and the current of the battery cell 10 while active balancing is performed in step S31 may be performed together while the performing of active balancing in step S13 is performed. The module management system 21 may sense the voltage and the current of the battery cell 10 subjected to active balancing and may provide the same to the rack management system 31.

The measuring of the voltage and the current of the battery cell 10 while passive balancing is performed in step S32 may be performed together while the performing of passive balancing in step S15 is performed. The module management system 21 may sense the voltage and the current of one or more battery cells 10 subjected to passive balancing and may provide the same to the rack management system 31.

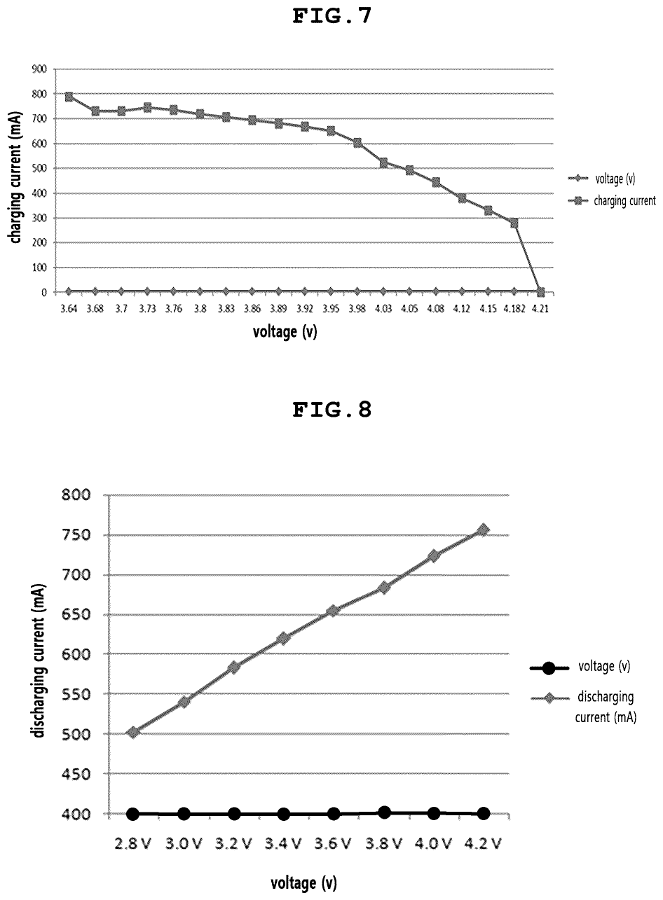

The determining of whether the current corresponding to the voltage of the battery cell 10 is out of the determined range in the reference graph in step S33 may be performed after active balancing or passive balancing is performed. The reference graph is a graph obtained by measuring and recording the current values corresponding to the voltages during the process of charging or discharging the battery cell 10 in the normal state. The reference graph may be stored in the rack management system 31. The reference graph may be stored in the form of a table in the battery management system (N1). The reference graph (see FIG. 7) comparing the voltage and current of active balancing may be a graph obtained during the charging process, and the reference graph (see FIG. 8) comparing the voltage and current of passive balancing may be a graph obtained during the discharging process.

FIG. 7 is a diagram illustrating a reference graph used for diagnosis during active balancing, according to an embodiment. FIG. 8 is a diagram illustrating a reference graph used for diagnosis during passive balancing, according to an embodiment.

FIG. 7 is a reference graph generated by measuring a voltage and a current while a battery cell 10 in a normal state is charged. The reference graph may include a plurality of voltage determination points. The plurality of voltage determination points may be positioned at intervals of a few mV to several tens of mV. For example, as shown in FIG. 7, the plurality of voltage determination points may be positioned at intervals of about 0.03 V in a range of 3.64 V to 4.2 V.

Current values corresponding to the voltage determination points may be obtained through measurement. Herein, a range of current values corresponding to voltages may be determined as a range of 80% to 120% of the current values. In order to more precisely determine abnormality, a range of current values may be determined as a range of 90% to 110% of the current values. The range of current values is a criterion for determining normality and may be determined in a variety of ranges.

FIG. 7 is a reference graph generated by measuring a voltage and a current while a battery cell 10 in a normal state is discharged. The reference graph may include a plurality of voltage determination points. For convenience of description, FIG. 8 shows the spacing of the voltage determination points in a larger scale. The plurality of voltage determination points may be positioned at intervals of a few mV to several tens of mV. For example, as shown in FIG. 7, the plurality of voltage determination points may be positioned at intervals of about 0.03 V in a range of 2.8 V to 4.2V. Current values corresponding to the voltage determination points may be obtained through measurement. Herein, a range of current values corresponding to voltages may be determined as a range of 90% to 110% of the current values or a range of 80% to 120% of the current values.

FIG. 6 will be referred to again.

The battery management system (N1) may determine the voltage determination points in the reference graph corresponding to the voltages measured during active balancing or passive balancing of battery cell 10, and may compare currents or a range of currents corresponding to the voltage determination points to currents measured during active balancing or passive balancing of the battery cell 10.

When the current corresponding to the voltage of the battery cell 10 is out of the range in the reference graph (Y), it may be determined that the battery cell 10 is in the abnormal state. The current corresponding to the voltage being out of the range in the reference graph may mean that the battery cell 10 is abnormal and normal charging or discharging is not performed.

When the current corresponding to the voltage of the battery cell 10 is in the range in the reference graph (N), it may be determined that the battery cell 10 is in the normal state. This current is similar to the current value corresponding to the voltage measured during charging or discharging of the battery cell 10 in the normal state, so it may be determined that the battery cell 10 is in the normal state.

As described above, while balancing of the battery cell 10 is performed, the measured voltage and current are compared to the reference graph to diagnose the state of the battery cell 10. Therefore, balancing and diagnosis may be performed simultaneously.

Further, a method for battery cell balancing according to an embodiment may simultaneously perform two diagnosis methods described with reference to FIGS. 5 and 6. The method for battery cell balancing may further include a double check step in which it is determined that the battery cell 10 is in the abnormal state when the absolute value of the difference obtained by subtracting the number of times that passive balancing is performed from the number of times that active balancing is performed is greater than the reference value and the current value corresponding to the voltage measured during active balancing is out of the range in the reference graph.

For example, when the number of times that active balancing is performed on a particular battery cell 10 is large, but the degradation states of all the battery cells 10 are insignificant in practice, the current value corresponding to the voltage measured during active balancing may fall within a range in a reference table. In this case, it is reasonable to determine that the particular battery cell 10 is in the normal state, and the battery cell 10 may continue to be used without replacement. The double check step may prevent a normal battery cell 10 from being detected as in the abnormal state.

The present disclosure has been described in detail above through detailed embodiments. The above description is only an example to which the principle of the present disclosure is applied, and other constitutions may be further included without departing from the scope of the present disclosure.

What is claimed is:

1. An apparatus for battery cell balancing, the apparatus comprising:
a plurality of passive balancing resistors respectively connected in parallel to a plurality of battery cells;
a plurality of passive balancing switches respectively connected in series to the plurality of passive balancing resistors, and configured to connect or disconnect the plurality of passive balancing resistors in parallel to or from the plurality of battery cells;
a charging element configured to convert power received from a power source for active balancing and supply a result of conversion to the plurality of battery cells;
a plurality of switching elements respectively connected to the plurality of battery cells, and configured to connect or disconnect the plurality of battery cells to or from the charging element; and
a battery management system configured to sense a state of charge of each of the plurality of battery cells, and control the plurality of passive balancing switches or the plurality of switching elements such that active balancing is performed on one battery cell with the lowest state of charge among the plurality of battery cells and passive balancing is performed on one or more battery cells with the states of charge higher than a reference value among the plurality of battery cells.

2. The apparatus of claim 1, wherein each of the plurality of switching elements comprises:
a first contact point connected to a first output terminal of the charging element from which power for active balancing is output;
a second contact point connected to one end of the battery cell;
a third contact connected to a second output terminal of the charging element from which power for active balancing is output; and
a fourth contact connected to the other end of the battery cell,
wherein each of the plurality of switching elements is configured to connect the first contact point to the second contact point and connect the third contact to the fourth contact when a control signal is input from the battery management system.

3. The apparatus of claim 1, wherein the charging element comprises:
a power input terminal configured to receive power from the power source;
a ground terminal connected to the ground;
a first output terminal from which power for active balancing is output;
a second output terminal from which power for active balancing is output; and
a power conversion circuit configured to convert power received from the power input terminal and the ground terminal and output a result of conversion to the first output terminal and the second output terminal, and including a first circuit connecting the power input terminal and the ground terminal and a second circuit connecting the first output terminal and the second output terminal, the first and the second circuit being electrically insulated.

4. The apparatus of claim 3, wherein the power source is the one or more battery cells with the states of charge higher than the reference value among the plurality of battery cells, a power converter configured to convert commercial power and provide power for active balancing to the charging element, or a balancing battery existing independently of the plurality of battery cells and configured to output power for active balancing.

5. The apparatus of claim 1, wherein the battery management system is configured to count, for each of the plurality of battery cells, the number of times that active balancing or passive balancing is performed, and determine that the battery cell is in an abnormal state when an absolute value of a difference between the number of times that active balancing is performed and the number of times that passive balancing is performed is greater than a reference number of times.

6. The apparatus of claim 1, wherein the battery management system is configured to compare a current corresponding to a voltage of each of the plurality of battery cells to a determined range in a reference graph while active balancing or passive balancing is performed, and determine that, when the current corresponding to the voltage of the battery cell is out of the determined range in the reference graph, the battery cell is in an abnormal state.

7. The apparatus of claim 1, wherein the battery management system comprises:
a module management system configured to manage a battery module comprising the plurality of battery cells;
a rack management system configured to manage a battery rack comprising a plurality of the battery modules; and
an energy management system configured to manage an energy storage system comprising a plurality of the battery racks,
wherein the module management system is configured to
output a control signal for performing active balancing and passive balancing of the plurality of battery cells,
the rack management system is configured to
control the module management system such that active balancing and passive balancing of the plurality of battery cells are performed,
count, for each of the plurality of battery cells, the number of times that active balancing is performed and the number of times that passive balancing is performed, and determine that the battery cell is in an abnormal state when an absolute value of a difference between the number of times that active balancing is performed and the number of times that passive balancing is performed is greater than a reference value, and
compare a voltage and a current of each of the plurality of battery cells to a determined range in a reference graph, and determine that, when the voltage and the current of the battery cell is out of the determined range in the reference graph, the battery cell is in the abnormal state, and
the energy management system is configured to control the module management system and the rack management system, and forward active balancing results, passive balancing results, and results of diagnosing the plurality of battery cells to a high-level system.

8. A method for battery cell balancing, the method comprising:
sensing, by a battery management system, states of charge of a plurality of battery cells;
determining, by the battery management system, whether each of the plurality of battery cells satisfies an active balancing condition;
controlling, by the battery management system, a switching element connected to the battery cell satisfying the active balancing condition and performing active balancing in which a charging element outputting power is connected to the battery cell satisfying the active balancing condition;
determining, by the battery management system, whether each of the plurality of battery cells satisfies a passive balancing condition; and
controlling, by the battery management system, a plurality of passive balancing switches respectively connected to one or more battery cells satisfying the passive balancing condition among the plurality of battery cells and performing passive balancing in which the one or more battery cells satisfying the passive balancing condition are connected to passive balancing resistors connected to the one or more battery cells.

9. The method of claim 8, further comprising:
determining whether the states of charge of all of the plurality of battery cells are in a determined range,
wherein balancing is terminated when the states of charge of the plurality of battery cells are in the determined range, or feedback is provided to start balancing again from the beginning when any battery cell with the state of charge out of the determined range exists among the plurality of battery cells.

10. The method of claim 8, wherein the active balancing condition means among the plurality of battery cells, a difference between a voltage of the battery cell with the lowest state of charge and a voltage of the battery cell with the next lowest state of charge is greater than a reference value, and
the passive balancing condition means among the remaining battery cells other than the battery cell satisfying the active balancing condition, a deviation of a voltage of the battery cell is greater than a reference deviation.

11. The method of claim 8, wherein the switching element comprises:
a first contact point connected to a first output terminal of the charging element from which power for active balancing is output;
a second contact point connected to one end of the battery cell;
a third contact connected to a second output terminal of the charging element from which power for active balancing is output; and
a fourth contact connected to the other end of the battery cell, and
in the performing of active balancing, when the battery management system inputs a control signal to the switching element, the first contact point is connected to the second contact point and the third contact is connected to the fourth contact and the battery cell with the lowest state of charge is charged with power output by the charging element.

12. The method of claim 8, further comprising:
after the performing of active balancing, a first counting step of increasing the number of times that active balancing is performed on the battery cell subjected to active balancing;
after the performing of passive balancing, a second counting step of increasing the number of times that passive balancing is performed on the battery cell subjected to passive balancing;
determining whether an absolute value of a difference between the number of times that active balancing is performed and the number of times that passive balancing is performed is greater than a reference number of times;
determining that the battery cell is in an abnormal state when the absolute value of the difference between the number of times that active balancing is performed and the number of times that passive balancing is performed is greater than the reference number of times; and
determining that the battery cell is in a normal state the absolute value of the difference between the number of times that active balancing is performed and the number of times that passive balancing is performed is equal to or less than the reference number of times.

13. The method of claim 8, further comprising:
measuring voltages and currents of the plurality of battery cells while active balancing is performed;
measuring voltages and currents of the plurality of battery cells while passive balancing is performed;
determining whether the current corresponding to the voltage of each of the plurality of battery cells is out of a determined range in a reference graph while active balancing or passive balancing is performed;
determining that, when the current corresponding to the voltage of the battery cell is out of the determined range in the reference graph, the battery cell is in an abnormal state; and
determining that, when the current corresponding to the voltage of the battery cell is in the determined range in the reference graph, the battery cell is in a normal state.

14. The method of claim 8, wherein the battery management system comprises:
a module management system configured to manage a battery module comprising the plurality of battery cells;
a rack management system configured to manage a battery rack comprising a plurality of the battery modules; and
an energy management system configured to manage an energy storage system comprising a plurality of the battery racks, and
the determining of whether the active balancing condition is satisfied and the determining of whether the passive balancing condition is satisfied are performed by the rack management system, and
the performing of active balancing and the performing of passive balancing are performed by the module management system.
